(19) United States
(12) Patent Application Publication
(10) Pub. No.: US 2009/0015313 A1
(43) Pub. Date: Jan. 15, 2009

(54) Level Shift Circuit and Semiconductor Integrated Circuit Including the Same

(76) Inventor: Tsuyoshi Matsushita, Osaka (JP)

Correspondence Address: MCDERMOTT WILL & EMERY LLP, 600 13TH STREET, N.W., WASHINGTON, DC, 20005-3096, US

(21) Appl. No.: 10/575,098

(22) PCT Filed: Oct. 27, 2005
(86) PCT No.: PCT/JP2005/019780

§ 371 Date: Apr. 10, 2006

(30) Foreign Application Priority Data
Feb. 17, 2005 (JP) 2005-041291

(51) Int. Cl. H03L 5/00

(52) U.S. Cl. 327/333

(57) ABSTRACT

In a level shift circuit, including two Nch transistors Tn1, Tn2 receiving a pair of complementary input signals and two Pch Transistors Tp1, Tp2 of which gate terminals are cross-coupled to each other, nodes A and B as the drains of the two Nch transistors Tn1, Tn2 operating in reverse to each other are connected together with a resistance Tp3. The resistance Tp3, constructed of a Pch transistor, is grounded at its gate to be in the normally ON state. For example, when the Nch transistors Tn1 and Tn2 go ON and OFF, respectively, a current initially flows from the high-potential node A through the resistance Tp3 to the low-potential node B, raising the potential at the low-potential node B. Thus, the potential rise at the node B is sped up compared with the case that only the Pch transistor Tp2 becoming ON contributes to the potential rise. This enables high-speed operation of the level shift circuit with a small number of elements.

### TECHNICAL FIELD

The present invention relates to a level shift circuit required for a semiconductor integrated circuit having different power-supply voltages.

### BACKGROUND ART

A conventional level shift circuit will be described.

FIG. 5 shows a conventional level shift circuit. Referring to FIG. 5, BUF1 denotes a buffer including inverters INV1, INV2 operating at a low power-supply voltage, BUF2 denotes a buffer including inverters INV3, INV4 operating at a high power-supply voltage, VDDH and VDDL respectively denote a high-voltage power supply and a low-voltage power supply, VSSH and VSSL respectively denote grounds (0V) for the high-voltage and low-voltage power supplies, Tn1 and Tn2 respectively denote first and second N-channel (Nch) MOS transistors, Tp1 and Tp2 respectively denote first and second P-channel (Pch) MOS transistors, IN denotes an input signal terminal, OUT denotes an output signal terminal, A denotes a node to which the drain of the Nch MOS transistor Tn1, the drain of the Pch MOS transistor Tp1 and the gate of the Pch MOS transistor Tp2 are connected, and B denotes a node to which the drain of the Nch MOS transistor Tn2, the drain of the Pch MOS transistor Tp2 and the gate of the Pch MOS transistor Tp1 are connected.

The sources of the Nch MOS transistors Tn1, Tn2 and the sources of the Pch MOS transistors Tp1, Tp2 are respectively connected to the ground VSSH for the high-voltage power supply and the high-voltage power supply VDDH. The input signal terminal IN is for inputting a signal of a low power-supply voltage into the buffer BUF1. Signals in opposite phase to and in phase with the input signal IN from the two inverters INV1, INV2 of the buffer BUF1 are input into the gates of the Nch MOS transistors Tn1, Tn2. The input of the buffer BUF2 on the output side is connected to the node B, and the output thereof is connected to the output signal terminal OUT.

The operation of the conventional level shift circuit configured as described above will be described.

When the input signal at the input signal terminal IN of the buffer BUF1 has changed its level from low to high, signals in opposite phase to and in phase with the input signal are supplied from the inverters INV1, INV2 of the buffer BUF1 to the gates of the Nch MOS transistors Tn2, Tn1, respectively. At this time, the Nch MOS transistor Tn2, to the gate of which the signal in opposite phase to the input signal, that is, the signal changing from high to low is applied, gradually increases its ON resistance, and this increases the drain-source voltage of the Nch MOS transistor Tn2. Roughly simultaneously with this, the Nch MOS transistor Tn1, to the gate of which the signal in phase with the input signal is applied, goes ON and gradually reduces its ON resistance, and this reduces the drain-source voltage of the Nch MOS transistor Tn1.

With the operation of the two Nch MOS transistors Tn1, Tn2 described above, the gate voltage of the Pch MOS transistor Tp2 falls, and thus the drain voltage thereof rises. This in return increases the gate voltage of the Pch MOS transistor Tp1. Once the input signal input into the buffer BUF1 finally reaches the high level, the drain-source of the Nch MOS transistor Tn1 becomes completely conducting, and thus the voltage of the node A becomes 0V. Also, the drain-source of the Nch MOS transistor Tn2 becomes completely non-conducting and the source-drain of the Pch MOS transistor Tp2 becomes conducting. Thus, the voltage of the node B becomes equal to the high power supply voltage VDDH. At this time, with the shift of the voltage of the node B to the high power-supply voltage VDDH, the buffer BUF2, which operates at the high power-supply voltage VDDH, shifts the potential of the output signal to be output from the output signal terminal OUT to the high power-supply voltage VDDH, and supplies this output signal to a high power-supply voltage operating circuit not shown.

On the contrary, when the input signal at the input signal terminal IN changes its level from high to low, signals in opposite phase to and in phase with the input signal are supplied from the inverters INV1, INV2 of the buffer BUF1 to the gates of the Nch MOS transistors Tn2, Tn1, respectively. At this time, the Nch MOS transistor Tn2, to the gate of which the signal in opposite phase to the input signal, that is, the signal changing from low to high is applied, goes ON and gradually reduces its ON resistance, and this reduces its drain-source voltage. Roughly simultaneously with this, the Nch MOS transistor Tn1, to the gate of which the signal in phase with the input signal is applied, gradually increases its ON resistance, and this increases its drain-source voltage.

With the operation of the two Nch MOS transistors Tn1, Tn2 described above, the gate voltage of the Pch MOS transistor Tp1 falls and thus the drain voltage thereof rises. This in turn increases the gate voltage of the Pch MOS transistor Tp2. Once the input signal input into the buffer BUF1 finally reaches the high level, the drain-source of the Nch MOS transistor Tn2 becomes completely conducting, and thus the voltage of the node B becomes 0V. At this time, with the shift of the voltage of the node B to 0V, the buffer BUF2, which operates at the high power-supply voltage VDDH, shifts the potential of the output signal to be output from the output signal terminal OUT to 0V, and supplies this output signal to a high power-supply voltage operating circuit not shown. Also, the drain-source of the Nch MOS transistor Tn1 becomes completely non-conducting and the source-drain of the Pch MOS transistor Tp1 becomes conducting. Thus, the voltage of the node A becomes equal to the high power-supply voltage VDDH.

As described above, with the conventional level shift circuit, it became possible to level-shift a signal output from a low power-supply voltage operating circuit to a signal of the high power-supply voltage VDDH and output the level-shifted signal to a high power-supply voltage operating circuit.

However, the conventional configuration described above had the following problem. When the input signal at the input signal terminal IN changes its level from high to low, for example, it takes one step for the source-drain of the Nch MOS transistor Tn2 to become conducting to thereby reduce the potential of the node B. From this state, it takes one more step for the source-drain of the Pch MOS transistor Tp1 to become conducting to thereby change the potential of the node A from low to high. That is, two steps are necessary until the potential states of the respective terminals of the Nch MOS transistors Tn1, Tn2 and the Pch MOS transistors Tp1, Tp2 are changed and the output state, a high level or a low level, is determined. This makes high-speed operation difficult.

As a conventional level shift circuit intended to solve the above problem, a level shift circuit disclosed in Patent Literature 1 is shown in FIG. 6. In the level shift circuit of FIG. 6, additional Nch MOS transistors Tn5, Tn4 are respectively connected in parallel with the two Pch MOS transistors Tp1, Tp2 of the level shift circuit shown in FIG. 5, and the complementary input signals from the buffer BUF1 are supplied to the gates of the Nch MOS transistors Tn5, Tn4.

In the level shift circuit of FIG. 6 with the configuration described above, when the complementary input signals from the buffer BUF1 operating at low power-supply voltage are reversed, one (for example, Tn1) of the pair of Nch MOS transistors Tn1, Tn2 is turned ON, changing the node A to a low level. Simultaneously, one (for example, Tn5) of the two additional Nch MOS transistors Tn5, Tn4 is turned ON, changing the node B to the high power-supply voltage VDDH. In this way, only one step is necessary to raise the output state to a high level.

### Patent Literature 1: Japanese Laid-Open Patent Publication No. 7-193488

### DISCLOSURE OF THE INVENTION

### Problems to be solved by the Invention

However, the conventional level shift circuit shown in FIG. 6 has a problem that the area increases with the addition of the two Nch MOS transistors Tn5, Tn4. Moreover, with the drains of the Nch MOS transistors Tn5, Tn4 directly connected to the high-voltage power supply VDDH, a reverse bias of the high power-supply voltage VDDH will be applied to the back gates and drains of the Nch MOS transistors Tn5, Tn4, depending on the fabrication process of semiconductor elements. This may degrade the reliability of the elements.

Furthermore, in the conventional level shift circuit, the two Nch MOS transistors Tn5, Tn4 added for high-speed implementation must be operated regardless of the frequency of the input signal IN. Therefore, if the input signal IN is low in frequency requiring no high-speed level shift operation, power consumption will wastefully increase by the redundant operation of the Nch MOS transistors Tn5, Tn4.

In view of the technical problems described above, the first object of the present invention is achieving speedup of the operation of a level shift circuit with a smaller number of elements than in the conventional one while securing high level of reliability of the elements.

The second object of the present invention is achieving low power consumption by stopping the operation of added elements when low-speed level shift operation is enough.

### Means for Solving the Problems

To attain the first object described above, the present invention adopts a configuration that two nodes A and B are connected with each other via a resistance in the conventional level shift circuit shown in FIG. 4.

To attain the second object described above, the present invention adopts a configuration that the above additional resistance is composed of one normally ON transistor and this transistor is turned OFF as required.

Specifically, the level shift circuit of the present invention includes: first and second P-channel transistors of which sources are connected to a high-voltage power supply; and first and second N-channel transistors of which sources are grounded, wherein complementary input signals in phase with and in opposite phase to an input signal from a low power-supply voltage operating circuit are respectively inputted to gates of the first and second N-channel transistors, a drain of the first N-channel transistor is connected to a drain of the first P-channel transistor and a gate of the second P-channel transistor, a drain of the second N-channel transistor is connected to a drain of the second P-channel transistor and a gate of the first P-channel transistor, the level shift circuit further comprises a resistance connecting the drain of the first N-channel transistor with the drain of the second N-channel transistor, and the drain of the second N-channel transistor serves as an output terminal to a high power-supply voltage operating circuit.

In the level shift circuit described above, the resistance is constructed of a P-channel transistor, and the P-channel transistor is grounded at its gate, connected to the drain of the first N-channel transistor at its source, and connected to the drain of the second N-channel transistor at its drain, to be in the normally ON state.

In the level shift circuit described above, the resistance is constructed of an N-channel transistor, and the N-channel transistor is connected to a high-voltage power supply at its gate, connected to the drain of the first N-channel transistor at its source, and connected to the drain of the second N-channel transistor at its drain, to be in the normally ON state.

In the level shift circuit described above, the resistance is constructed of a P-channel transistor, and the P-channel transistor receives an ON/OFF operation switch signal at its gate, connected to the drain of the first N-channel transistor at its source, and connected to the drain of the second N-channel transistor at its drain.

In the level shift circuit described above, the resistance is constructed of an N-channel transistor, and the N-channel transistor receives an ON/OFF operation switch signal at its gate, connected to the drain of the first N-channel transistor at its source, and connected to the drain of the second N-channel transistor at its drain.

In the level shift circuit described above, the ON/OFF operation switch signal is an operation mode switch signal received from outside.

In the level shift circuit described above, the drains of the first and second N-channel transistors serve as differential output terminals for the high power-supply voltage operating circuit.

The semiconductor integrated circuit of the present invention includes the level shift circuit described above.

As described above, according to the present invention, in the case of input of a high-speed signal, when the input signal is reversed, a current is supplied from a node on the high potential side, out of nodes A, B on the low and high potential sides, to the node on the low potential side that is to shift to the high potential side through a resistance. This permits the node on the low potential side to raise its potential swiftly to become high potential. Accordingly, the shift of the node on the low potential side to high potential can be sped up. Also, since the resistance provided additionally is a one-element resistance made up of one transistor, the number of elements can be reduced by one compared with the conventional example shown in FIG. 5. Moreover, with one transistor as the resistance, no reverse bias of the high power-supply voltage will be applied between its back gate and drain, and thus the reliability is highly secured.

In particular, according to the present invention, when a low-speed input signal is input, one transistor constituting the resistance is turned OFF (non-conducting) to stop high-speed operation. This can save redundant power consumption with the additional transistor (resistance)

### EFFECT OF THE INVENTION

As described above, in the level shift circuit and the semiconductor integrated circuit of the present invention, a current is supplied from a node on the high potential side to a node on the low potential side that is to shift to the high potential side through a resistance, to thereby enable speedup of the level shift circuit, while the resistance is made up of one element and the element is prevented from being exposed to a high power-supply voltage, to thereby highly secure its reliability.

In particular, according to the level shift circuit of the present invention, when a low-speed input signal is input, the additional transistor (resistance) is turned OFF to thereby enable saving of redundant power consumption of the transistor.

### BRIEF DESCRIPTION OF THE DRAWINGS

FIG. 1 is a view showing a level shift circuit of Embodiment 1 of the present invention.

FIG. 2 is a view showing a level shift circuit of Embodiment 2 of the present invention.

FIG. 3 is a view showing a level shift circuit of Embodiment 3 of the present invention.

FIG. 4 is a view showing a level shift circuit of Embodiment 4 of the present invention.

FIG. 5 is a view showing a conventional level shift circuit.

FIG. 6 is a view showing a conventional level shift circuit improved from the level shift circuit of FIG. 5.

### DESCRIPTION OF REFERENCE NUMERALS

Tp1 First Pch MOS transistor
Tp2 Second Pch MOS transistor
Tn1 First Nch MOS transistor
Tn2 Second Nch MOS transistor
Tp3, Tp4 Pch MOS transistors (resistances)
Tn3 Nch MOS transistor (resistance)
Tn4 Nch MOS transistor
Tn5 Nch MOS transistor
BUF1, BUF2, BUF3 Buffers
A, B Nodes
IN Input terminal
OUT Output terminal
OUTP, OUTN Differential output terminals
VDDH High power-supply voltage
VDDL Low power-supply voltage
VSSH Ground for high power-supply voltage
VSSL Ground for low power-supply voltage
Stb Standby mode signal
   (ON/Off Switch Signal and Operation Mode Switch Signal)

### BEST MODE FOR CARRYING OUT THE INVENTION

Hereinafter, level shift circuits of embodiments of the present invention will be described in detail with reference to the drawings.

### Embodiment 1

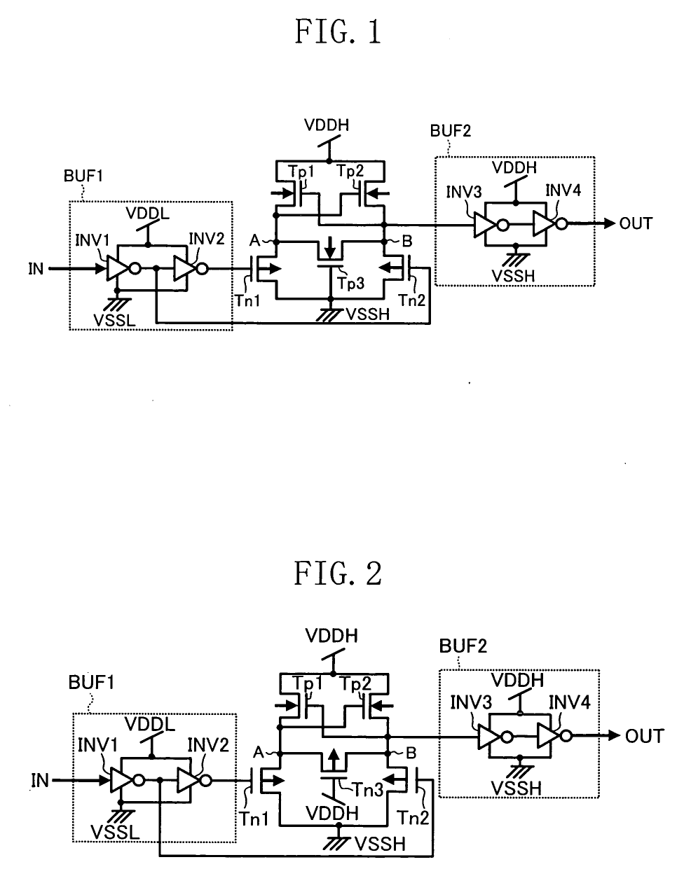

FIG. 1 shows a configuration of a level shift circuit of Embodiment 1 of the present invention.

Referring to FIG. 1, BUF1 denotes a buffer on the input side including inverters INV1, INV2 operating at a low power-supply voltage VDDL and a ground (0V) VSSL for this voltage, and BUF2 denotes a buffer on the output side including inverters INV3, INV4 operating at a high power-supply voltage VDDH. The buffers BUF1 and BUF2 should just have a buffer function, and are not necessarily a circuit having multi-stage connection of inverters.

Also referring to FIG. 1, Tn1, Tn2 denote first and second Nch MOS transistors of which sources are connected to the ground (0V) VSSH for the high-voltage power supply VDDH. Tp1, Tp2 denote first and second Pch MOS transistors of which sources are connected to the high-voltage power supply VDDH. IN denotes an input terminal for an input signal of a low power-supply voltage to be input into the buffer BUF1 on the input side (hereinafter, the input signal itself is also referred to as IN). The input signal IN is supplied from a low power-supply voltage operating circuit not shown.

The output of the first-stage inverter INV1 of the buffer BUF1 on the input side, that is, a signal in opposite phase to the input signal IN is input into the gate of the second Nch MOS transistor Tn2, while the output of the second-stage inverter INV2, that is, a signal in phase with the input signal IN is input into the gate of the first Nch MOS transistor Tn1.

The drain of the Nch MOS transistor Tn1 is connected to the drain of the Pch MOS transistor Tp1, and the connection point thereof is referred to as node A. The node A is connected to the gate of the Pch MOS transistor Tp2. Likewise, the drain of the Nch MOS transistor Tn2 is connected to the drain of the Pch MOS transistor Tp2, and the connection point thereof is referred to as node B. The node B is connected to the gate of the Pch MOS transistor Tp1.

The first-stage inverter INV3 of the buffer BUF2 is connected to the node B, and an output signal of the high power-supply voltage VDDH from the second-stage inverter INV4 is output externally from the output terminal OUT (hereinafter, the output signal is also referred to as OUT).

The two nodes A and B are connected with each other via a Pch MOS transistor Tp3 as a resistance. Specifically, the Pch MOS transistor (resistance) Tp3 is connected to the node A at its source and to the node B at its drain, and the ground VSSH for the high-voltage power supply is connected to its gate, to allow for normally ON operation.

Hereinafter, the operation of the level shift circuit will be described.

When the input signal at the input signal terminal IN changes its level from low to high, signals in opposite phase to and in phase with the input signal are supplied from the two inverters INV1, INV2 of the buffer BUF1, which is a low power-supply voltage operation circuit, to the gates of the Nch MOS transistors Tn2, Tn1. At this time, the Nch MOS transistor Tn2, to the gate of which the signal in opposite phase to the input signal IN, that is, a signal changing from high to low is applied, gradually increases its ON resistance. This increases the drain-source voltage of the Nch MOS transistor Tn2, and thus the level of the node B starts to rise. Roughly simultaneously with this, the Nch MOS transistor Tn1, to the gate of which the signal in phase with the input signal IN is applied, starts going ON, allowing a current to start flowing from the node A to the ground VSSH through the Nch MOS transistor Tn1, and thus ON resistance of the Nch MOS transistor Tn1 gradually decreases. This reduces the drain-source voltage of the Nch MOS transistor Tn1, and thus lowers the level of the node A.

With the shift of the node A to the low level, the gate voltage of the Pch MOS transistor Tp2 decreases, causing start of ON operation, and thus the drain voltage of the Pch MOS transistor Tp2, that is, the level of the node B rises. The node B shifting to the high-level side was in the low level before the change of the input signal IN, and the node A shifting to the low-level side was in the high level before the change of the input signal IN. Therefore, simultaneously with, or from the stage prior to, the start of the ON operation of the Pch MOS transistor Tp2, a current flows from the node A on the high-level side to the node B on the low-level side through the resistance (Pch MOS transistor) Tp3, and this speeds up the potential rise at the node B shifting to the high-level side.

Thanks to the speedup of the potential rise at the node B shifting to the high-level side, the time taken for the potential at the node B to exceed the threshold voltage of the first-stage inverter INV3 of the buffer BUF2 on the output side operating at a high power-supply voltage is shortened, allowing the output from the output terminal OUT of the buffer BUF2 to reach the high power-supply voltage VDDH early. With the potential rise at the node B, also, the gate voltage of the Pch MOS transistor Tp1 rises. The Pch MOS transistor Tp1 therefore starts OFF operation, making it difficult to supply the high power-supply voltage VDDH, and thus the level fall of the node A continues. Although the node B shifting to the high-level side is on the grounding route from the high-voltage power supply VDDH through the Pch MOS transistor Tp2, the resistance (Pch MOS transistor) Tp3 and the Nch MOS transistor Tn1 down to the ground, it is located upstream of the resistance (Pch MOS transistor) Tp3. Therefore, by appropriately setting the resistance value of the resistance Tp3, the potential level of the node B that has shifted to the high-level side is prevented from decreasing to below the threshold voltage of the first-stage inverter INV3 of the buffer BUF2 on the output side after it has once exceeded the threshold voltage.

Contrary to the above, when the level of the input signal at the input signal terminal IN changes its level from high to low, operation reverse to the operation described above is performed. Specifically, the Nch MOS transistor Tn2, to the gate of which a signal in opposite phase to the input signal IN, that is, a signal changing from low to high is applied, starts going ON, allowing a current to start flowing from the node B to the ground VSSH through the Nch MOS transistor Tn2, and thus ON resistance of the Nch MOS transistor Tn2 gradually decreases. This reduces the drain-source voltage of the Nch MOS transistor Tn2 and thus lowers the level of the node B. Roughly simultaneously with this, the Nch MOS transistor Tn1, to the gate of which a signal in phase with the input signal IN is applied, gradually increases its ON resistance. This increases the drain-source voltage of the Nch MOS transistor Tn1, and the level of the node A starts to rise.

With the shift of the node B to the low level, the gate voltage of the Pch MOS transistor Tp1 falls, causing start of ON operation, and thus the drain voltage of the Pch MOS transistor Tp1, that is, the level of the node A rises. The node A shifting to the high-level side was in the low level before the change of the input signal IN, and the node B shifting to the low-level side was in the high level before the change of the input signal IN. Therefore, simultaneously with, or from the stage prior to, the start of the ON operation of the Pch MOS transistor Tp1, a current flows from the node B on the high-level side to the node A on the low-level side through the resistance (Pch MOS transistor) Tp3, and this speeds up the potential rise at the node A shifting to the high-level side.

Thanks to the speedup of the potential rise at the node A shifting to the high-level side, the gate voltage of the Pch MOS transistor Tp2 rises swiftly, allowing the Pch MOS transistor Tp2 to start going OFF early. Therefore, the supply of the high power-supply voltage VDDH becomes difficult, and this speeds up the level fall of the node B. This results in shortening the time taken for the level of the node B to become below the threshold voltage of the first-stage inverter INV3 of the buffer BUF2 operating at a high power-supply voltage, allowing the output signal from the output terminal OUT of the buffer BUF2 to become the ground voltage VDDL early.

In the level shift circuit of this embodiment shown in FIG. 1, the potential at the node A or B on the high-level side is a potential determined by the resistance division among the three serially-connected transistors (Tp1, Tp3 and Tn2) or (Tp2, Tp3 and Tn1) that are in the ON state, and will not be the high power-supply voltage VDDH. Therefore, in the transistor Tp3 additionally supplied, the conventional trouble that a reverse bias of the high power-supply voltage VDDH is applied to its back gate and drain can be avoided, and thus reliability is well secured.

### Embodiment 2

A level shift circuit of Embodiment 2 of the present invention will be described.

FIG. 2 shows a configuration of the level shift circuit of Embodiment 2. The level shift circuit shown in FIG. 2 is different from the level shift circuit of FIG. 1 in that the transistor constituting the resistance was the Pch MOS transistor Tp3 in FIG. 1 but is a Nch MOS transistor Tn3 in this embodiment. Specifically, the Nch MOS transistor (resistance) Tn3 is connected to the node A at its source and to the node B at its drain, and the gate thereof is connected to the high-voltage power supply VDDH, to allow for normally ON operation.

Therefore, in this embodiment, also, the same function and effect as those in Embodiment 1 can be obtained.

### Embodiment 3

A level shift circuit of Embodiment 3 of the present invention will be described.

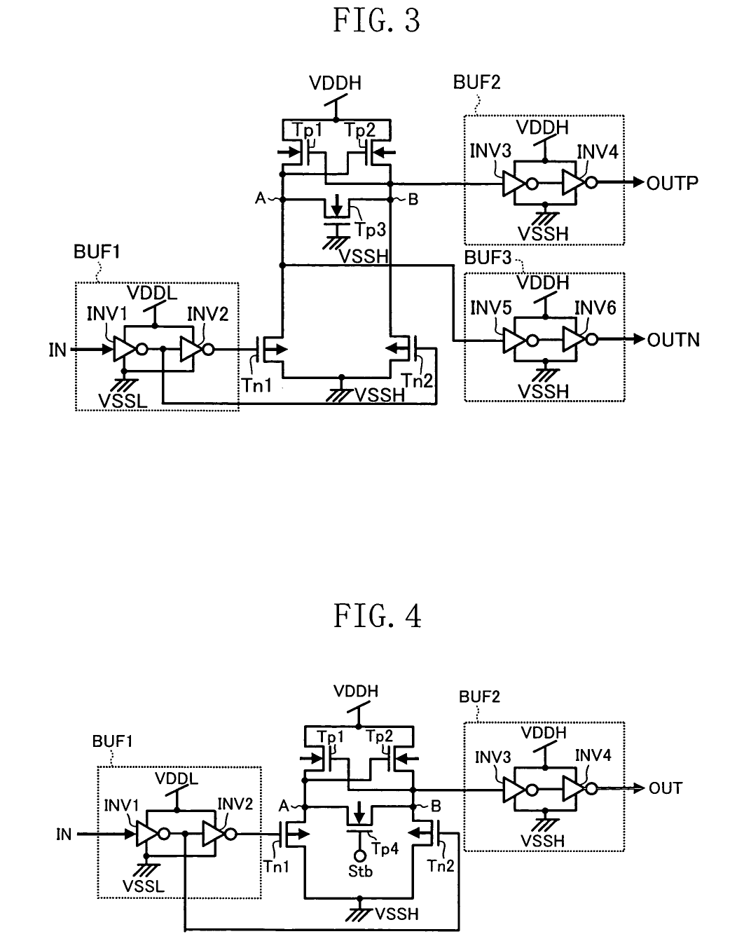

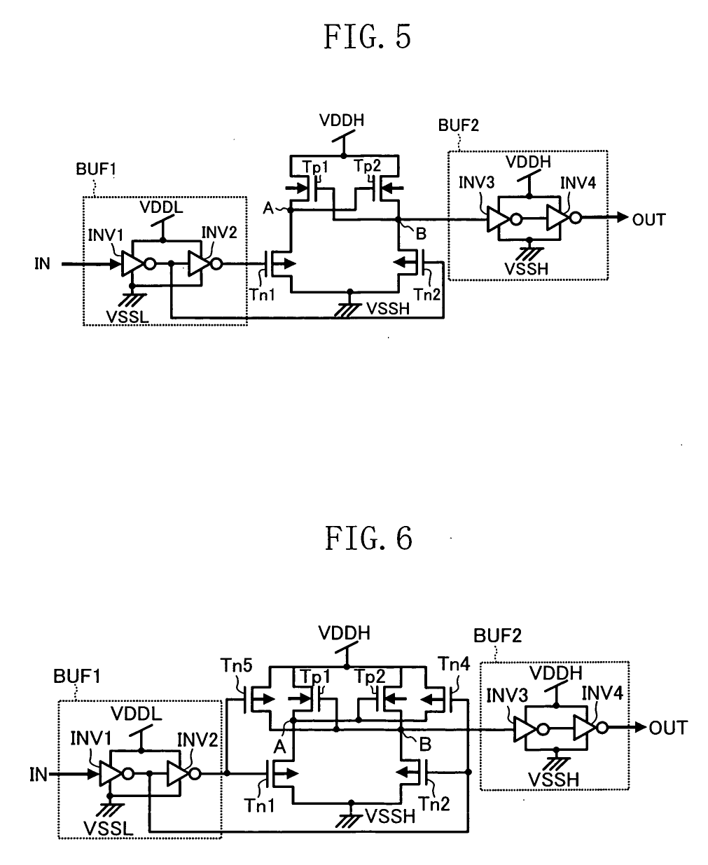

FIG. 3 shows a configuration of the level shift circuit of Embodiment 3. The level shift circuit shown in FIG. 3, of which output signal is a differential signal, is different from the level shift circuit of FIG. 1 in that a buffer BUF3 is additionally provided on the output side.

The buffer BUF3 on the output side includes two inverters INV5, INV6 operating at the high power-supply voltage VDDH and the corresponding ground VSSH. The first-stage inverter INV5 is connected to the node A. The outputs of the two buffers BUF2 and BUF3 on the output side are connected to an output terminal OUTP outputting a signal in phase with the input signal IN and an output terminal OUTN outputting a signal in opposite phase to the input signal IN, respectively. The output terminals OUTP and OUTN constitute a pair of differential output terminals.

In this embodiment, although the placement of the pair of differential output terminals OUTP and OUTN was applied to the level shift circuit of FIG. 1, this placement is also applicable to the level shift circuit of FIG. 2.

### Embodiment 4

FIG. 4 shows a level shift circuit of Embodiment 4 of the present invention.

The level shift circuit shown in FIG. 4 is the same in configuration as the level shift circuit shown in FIG. 1, except that a Pch MOS transistor Tp4 for connecting the two nodes A and B receives a standby mode signal Stb at its gate as an ON/OFF operation switch signal. In the normal operation mode in which a high-frequency high-speed signal is input via the input terminal IN, the standby mode signal (operation mode switch signal) Stb falls to the low level VSSH, to put the Pch MOS transistor (resistance) Tp4 additionally provided in the normally ON state. In the standby mode in which a low-frequency low-speed signal is input via the input terminal IN, the standby mode signal Stb rises to the high level VDDH, to put the Pch MOS mode transistor (resistance) Tp4 in the normally OFF state. The standby mode signal Stb is supplied from an LSI (semiconductor integrated circuit) including the level shift circuit of this embodiment.

In this embodiment, therefore, in the standby mode, in which a low-frequency low-speed signal is input via the input terminal IN, no high-speed level shift operation is necessary for the level shift circuit, but normal speed is enough. In this situation, the standby mode signal Stb of the high level VDDH is input, to put the Pch MOS transistor (resistance) Tp4 in the normally OFF state. In this state, the operation of speeding up the potential rise at the node shifting to the high level with supply of a current from the node on the high level side is stopped. Therefore, the level shift circuit performs normal-speed level shift operation. In this way, in the standby mode, redundant operation as conventionally done is not involved, and thus lower power consumption than in the conventional case can be achieved.

In this embodiment, the standby mode signal Stb was input into the Pch MOS transistor (resistance) Tp4. Alternatively, a sleep mode signal and the like may be used. The level shift circuit of FIG. 1 was modified to obtain the level shift circuit of this embodiment. Naturally, the level shift circuits of FIG. 2 and FIG. 3 may be modified to obtain the level shift circuit of this embodiment. In the case using the Nch MOS transistor (resistance) Tn3, the standby mode signal Stb of the low level VSSL may be input in the standby mode.

The level shift circuits of the present invention were described with reference to FIGS. 1 to 4. The present invention also includes a semiconductor integrated circuit having any of such level shift circuits, a low power-supply voltage operating circuit and a high power-supply voltage operating circuit, in which an output signal from the low power-supply voltage operating circuit is level-shifted to a high power-supply voltage VDDH and the voltage VDDH is output to the high power-supply voltage operating circuit.

### INDUSTRIAL APPLICABILITY

According to the present invention, with only addition of one resistance, high-speed level shift operation can be attained while the reliability of the resistance is well secured. Therefore, the present invention is useful as a small-size level shift circuit for level-shifting a low-voltage signal to a high-voltage signal at high speed in propagation of a signal between a plurality of circuit sections having different power-supply voltages, and a semiconductor integrated circuit including such a level shift circuit and the plurality of circuit sections.

1. A level shift circuit comprising:
first and second P-channel transistors of which sources are connected to a high-voltage power supply; and
first and second N-channel transistors of which sources are grounded,
wherein complementary input signals in phase with and in opposite phase to an input signal from a low power-supply voltage operating circuit are respectively inputted to gates of the first and second N-channel transistors,
a drain of the first N-channel transistor is connected to a drain of the first P-channel transistor and a gate of the second P-channel transistor,
a drain of the second N-channel transistor is connected to a drain of the second P-channel transistor and a gate of the first P-channel transistor,
the level shift circuit further comprises a resistance connecting the drain of the first N-channel transistor with the drain of the second N-channel transistor, and
the drain of the second N-channel transistor serves as an output terminal to a high power-supply voltage operating circuit.

2. The level shift circuit of claim 1,
wherein the resistance is constructed of a P-channel transistor, and
the P-channel transistor is grounded at its gate, connected to the drain of the first N-channel transistor at its source, and connected to the drain of the second N-channel transistor at its drain, to be in the normally ON state.

3. The level shift circuit of claim 1,
wherein the resistance is constructed of an N-channel transistor, and
the N-channel transistor is connected to a high-voltage power supply at its gate, connected to the drain of the first N-channel transistor at its source, and connected to the drain of the second N-channel transistor at its drain, to be in the normally ON state.

4. The level shift circuit of claim 1,
wherein the resistance is constructed of a P-channel transistor, and
the P-channel transistor receives an ON/OFF operation switch signal at its gate, connected to the drain of the first N-channel transistor at its source, and connected to the drain of the second N-channel transistor at its drain.

5. The level shift circuit of claim 1,
wherein the resistance is constructed of an N-channel transistor, and
the N-channel transistor receives an ON/OFF operation switch signal at its gate, connected to the drain of the first N-channel transistor at its source, and connected to the drain of the second N-channel transistor at its drain.

6. The level shift circuit of claim 4,
wherein the ON/OFF operation switch signal is an operation mode switch signal received from outside.

7. The level shift circuit of claim 1,
wherein the drains of the first and second N-channel transistors serve as differential output terminals for the high power-supply voltage operating circuit.

8. A semiconductor integrated circuit comprising the level shift circuit of claim 1.
